(19) United States
(12) Patent Application Publication
(10) Pub. No.: US 2024/0313505 A1
(43) Pub. Date: Sep. 19, 2024

(54) MULTI-WAVELENGTH EXTERNAL CAVITY LASER

(71) Applicant: SANTEC HOLDINGS CORPORATION, Komaki (JP)

(72) Inventors: Changho CHONG, Los Altos, CA (US); Masayuki OKANO, Santa Clara, CA (US)

(73) Assignee: SANTEC HOLDINGS CORPORATION, Komaki (JP)

(21) Appl. No.: 18/121,817

(22) Filed: Mar. 15, 2023

(51) Int. Cl. H01S 5/14; H01S 5/12

(52) U.S. Cl. CPC H01S 5/141; H01S 5/1212

(57) ABSTRACT

Multi-wavelength external cavity laser devices are generally described. The device includes a gain medium, a reflector, a wavelength selective element, and a chirped grating reflector. The wavelength selective element filters light having a first wavelength, and the chirped grating reflector reflects the light having the first wavelength. The light travels back to the reflector. As a result, the chirped grating reflector and the reflector define an optical cavity for the light having the first wavelength.

### BACKGROUND

The following description is provided to assist the understanding of the reader. None of the information provided or references cited is admitted to be prior art.

Multi-wavelength laser sources have been considered for applications including optical interconnection, optical computing, quantum computing, and optical deep learning chips. Arrays of multiple lasers supporting different wavelengths can be coupled with a combiner/multiplexer, and a series of modulators and a series of wavelength selective detectors can be used to modulate the different wavelengths. However, the use of multiple lasers is costly, particularly when lasing a number of wavelengths is desired. Wavelength comb-generation based on non-linear optical effects can be another candidate, but the comb-generation requires additional power leveling. External cavity lasers (ECL) have been proposed for multi-wavelength laser sources, but their effective cavity length must be mechanically adjusted to achieve multi-wavelength lasing. Likewise, phase control is necessary for multiple-wavelength ECLs. When multiple filters are embedded in an ECL, multiple phase control is required to adjust each of the cavity lengths to lase at multiple wavelengths. Thus, a device and method that allows for lasing at multiple wavelengths without phase control or mechanical adjustment is desirable.

### SUMMARY

The present technology provides multi-wavelength external cavity laser devices and methods of using the same. In one embodiment, a multi-wavelength external cavity laser device includes a gain medium, a reflector optically coupled to the gain medium, a first wavelength selective element optically coupled to the gain medium and the reflector, the first wavelength selective element configured to filter light having a first wavelength, and a first chirped grating reflector optically coupled to the first wavelength selective element, wherein the first chirped grating reflector is configured to reflect a plurality of wavelengths including the first wavelength.

In some embodiments, a multi-wavelength external cavity laser device further includes a second wavelength selective element configured to filter light having a second wavelength, the second wavelength selective element optically coupled to the gain medium and the reflector, wherein the first chirped grating reflector is optically coupled to the second wavelength selective element, and wherein a first portion of the first chirped grating reflector is configured to reflect the light having the first wavelength and a second portion of the first chirped grating reflector is configured to reflect the light having the second wavelength.

In some embodiments, the light having the first wavelength and the light having the second wavelength are reflected from a different portion of the chirped grating reflector.

In some embodiments, the first wavelength selective element and the second wavelength selected element are connected in parallel, wherein the first wavelength is different from the second wavelength.

In some embodiments, the reflector and the first portion of the chirped grating reflector define a first optical cavity, such that the first wavelength selective element is located along a path of light resonating in the first optical cavity, and the reflector and the second portion of the first chirped grating reflector define a second optical cavity, such that the second wavelength selective element is located along a path of light resonating in the second optical cavity.

In some embodiments, the ratio of a length change of the first optical cavity to the length of the first optical cavity is approximately equal to the ratio of a wavelength change of light resonating in the first optical cavity to a center wavelength of a total wavelength tuning range of the first optical cavity, and the ratio of a length change of the second optical cavity to the length of the second optical cavity is approximately equal to the ratio of a wavelength change of light resonating in the second optical cavity to a center wavelength of a total wavelength tuning range of the second optical cavity.

In some embodiments, a multi-wavelength external cavity laser device further includes a second wavelength selective element configured to filter light having a second wavelength, the second wavelength selective element optically coupled to the gain medium and the reflector, and a second chirped grating reflector configured to reflect the light having the second wavelength, the second chirped grating reflector optically coupled to the second wavelength selective element. In some embodiments, the first wavelength is different from the second wavelength.

In some embodiments, the reflector and the first chirped grating reflector define a first optical cavity, such that the first wavelength selective element is located along a path of light resonating in the first optical cavity, and the reflector and the second chirped grating reflector define a second optical cavity, such that the second wavelength selective element is located along a path of light resonating in the second optical cavity.

In some embodiments, the ratio of a length change of the first optical cavity to the length of the first optical cavity is approximately equal to the ratio of a wavelength change of light resonating in the first optical cavity to a center wavelength of a total wavelength tuning range of the first optical cavity, and the ratio of a length change of the second optical cavity to the length of the second optical cavity is approximately equal to the ratio of a wavelength change of light resonating in the second optical cavity to a center wavelength of a total wavelength tuning range of the second optical cavity.

In some embodiments, the first wavelength selective element comprises a wavelength tunable filter.

In some embodiments, the first wavelength selective element comprises a micro-ring resonator filter.

In some embodiments, a multi-wavelength external cavity laser device further includes a beam-controlling component optically coupled to the first wavelength selective element, the beam-controlling component configured to control a characteristic of the light. In some embodiments, the beam-controlling component may be an optical attenuator.

Another aspect of the present invention includes a method of utilizing a multi-wavelength external cavity laser device. In one embodiment, the method includes generating light in an external cavity laser device, wherein the light has a plurality of wavelengths, directing or reflecting by a reflector, the light into a first wavelength selective element, filtering, by the first wavelength selective element, a portion of the light at a first wavelength, reflecting, by a first portion of a chirped grating reflector, the portion of the light at the first wavelength, and emitting the light at the first wavelength.

In some embodiments, the method further includes filtering, by a second wavelength selective element, a portion of the light at a second wavelength, and reflecting, by a second portion of the chirped grating reflector, the portion of the light at the second wavelength.

In some embodiments, the reflector and the first portion of the chirped grating reflector define a first optical cavity, such that the first wavelength selective element is located along a path of light resonating in the first optical cavity, the ratio of a length change of the first optical cavity to the length of the first optical cavity is approximately equal to the ratio of a wavelength change of light resonating in the first optical cavity to a center wavelength of a total wavelength tuning range of the first optical cavity, the reflector and the second portion of the chirped grating reflector define a second optical cavity, such that the second wavelength selective element is located along a path of light resonating in the second optical cavity, and the ratio of a length change of the second optical cavity to the length of the second optical cavity is approximately equal to the ratio of a wavelength change of light resonating in the second optical cavity to a center wavelength of a total wavelength tuning range of the second optical cavity.

In some embodiments, the method further includes filtering, by a second wavelength selective element, a portion of the light at a second wavelength, and reflecting, by a second chirped grating reflector, the portion of the light at the second wavelength.

In some embodiments, the reflector and the first chirped grating reflector define a first optical cavity, such that the first wavelength selective element is located along a path of light resonating in the first optical cavity, the ratio of a length change of the first optical cavity to the length of the first optical cavity is approximately equal to the ratio of a wavelength change of light resonating in the first optical cavity to a center wavelength of a total wavelength tuning range of the first optical cavity, the reflector and the second chirped grating reflector define a second optical cavity, such that the second wavelength selective element is located along a path of light resonating in the second optical cavity, and the ratio of a length change of the second optical cavity to the length of the second optical cavity is approximately equal to the ratio of a wavelength change of light resonating in the second optical cavity to a center wavelength of a total wavelength tuning range of the second optical cavity.

In some embodiments, the first wavelength selective element is a micro-ring resonator filter.

In some embodiments, the method further includes controlling, by a beam-controlling component, a characteristic of the light.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 depicts a representation of a multi-wavelength external cavity laser device that includes a chirped grating reflector and wavelength selective elements in accordance with an illustrative embodiment.

FIG. 2 depicts a representation of a multi-wavelength external cavity laser device that includes multiple chirped grating reflectors and wavelength selective elements in accordance with an illustrative embodiment.

FIG. 3A depicts a representation of a multi-wavelength external cavity laser device of FIG. 1 that includes optical attenuators to control a characteristic of light in accordance with an illustrative embodiment.

FIG. 3B depicts a representation of a multi-wavelength external cavity laser device of FIG. 2 that includes optical attenuators to control a characteristic of light in accordance with an illustrative embodiment.

FIG. 3C depicts an exemplary characteristic profile of light emitted from a multi-wavelength external cavity laser device of FIG. 3A or FIG. 3B, in accordance with an illustrative embodiment.

FIG. 4 depicts a method of using a multi-wavelength external cavity laser device in accordance with an illustrative embodiment.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Described herein is a multi-wavelength external cavity laser device that uses a chirped grating reflector and a wavelength selective element to stably operate a laser at multiple wavelengths without using a complicated phase control component.

As will be discussed in further detail below, a multi-wavelength external cavity laser device includes a chirped grating reflector and a wavelength selective element. A first wavelength selective element is configured to filter light having a first wavelength, and a second wavelength selective element is configured to filter light having a second wavelength. In some embodiments, a first portion of the chirped grating reflector is configured to reflect the light having the first wavelength, and a second portion of the chirped grating reflector is configured to reflect the light having the second wavelength. In some embodiments, a first chirped grating reflector is configured to reflect the light having the first wavelength, and a second chirped grating reflector is configured to reflect the light having the second wavelength. This allows for lasing at multiple wavelengths without using a complicated phase control component and enables faster response and tunability.

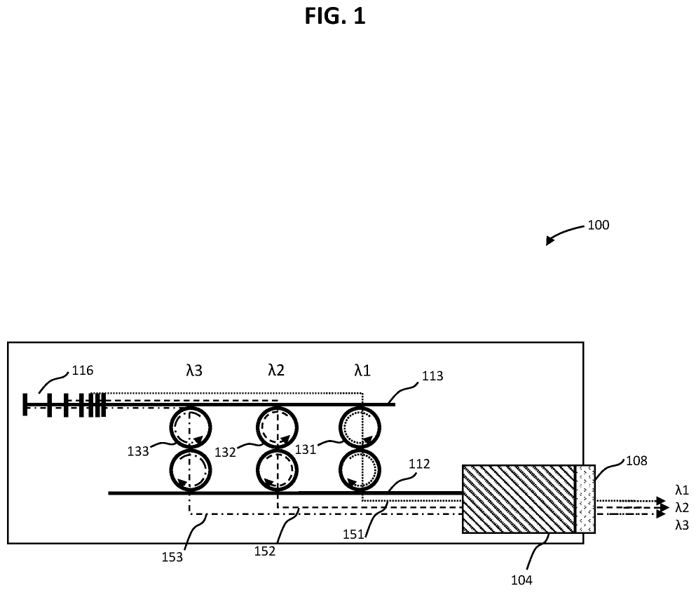

FIG. 1 depicts a multi-wavelength external cavity laser device 100 that includes a gain medium 104, a reflector 108, a first beam-transmitting component 112, a second beam-transmitting component 113, a chirped grating reflector 116, a first wavelength selective element 131, a second wavelength selective element 132, and a third wavelength selective element 133. A first light path 151 for a first wavelength (λ1), a second light path 152 for a second wavelength (λ2), and a third light path 153 for a third wavelength (λ3) are depicted as different dashed lines. The wavelength selective elements 131-133 are optically coupled to the gain medium 104 and the reflector 108 via the first beam-transmitting component 112, and the chirped grating reflector 116 is optically coupled to each of the wavelength selective elements 131-133 via the second beam-transmitting component 113.

In FIG. 1, the multi-wavelength external cavity laser device 100 is shown to include the gain medium 104. The gain medium 104 serves as an active medium of the laser device and is a source of stimulated photons (i.e., light) introduced into the multi-wavelength external cavity laser device 100. The light generated by the gain medium 104 travels to the wavelength selective elements 131-133 via the first beam-transmitting component 112 and are reflected off of the chirped grating reflector 116, as generally shown along the paths 151-153. The light having the first wavelength travels the first light path 151 (i.e., through the first wavelength selective element 131), the light having the second wavelength travels the second light path 152 (i.e., through the second wavelength selective element 132), and the light having the third wavelength travels the third light path 153 (i.e., through the third wavelength selective element 133). After reflecting off of the chirped grating reflector 116, the light travels back through the wavelength selective elements 131-133 and back through the gain medium 104. Again, the light having the first wavelength travels the first light path 151, the light having the second wavelength travels the second light path 152, and the light having the third wavelength travels the third light path 153. In some embodiments, a portion of the light may be emitted through the reflector 108.

In FIG. 1, the multi-wavelength external cavity laser device 100 is shown to include the reflector 108. The reflector 108 reflects at least a portion of light having wavelengths including the first wavelength. In some embodiments, the reflector 108 may reflect essentially all the light generated. In some embodiments, the reflectivity of the reflector 108 may be a function of wavelength. The reflector 108 may be or include any material, component, or device that can reflect light having wavelengths including the first wavelength. In some embodiments, the reflector 108 may be a loop mirror. In some embodiments, the reflector 108 may be omitted-in this case, a partial/high reflective coating on the gain medium 104 and/or a portion of the multi-wavelength external cavity laser device 100 may be used. In one embodiment, the partial/high reflective coating has a fraction percentage of only a few (e.g., 2-15%) percent reflection. The reflector 108 serves as a mirror that forms one end of an optical cavity. In some embodiments, the multi-wavelength external cavity laser device 100 may emit a laser output through the reflector 108, which can be adjusted by the amount of reflectivity of reflector 108.

In FIG. 1, the multi-wavelength external cavity laser device 100 is shown to include the first beam-transmitting component 112 and the second beam-transmitting component 113. The first beam-transmitting component 112 and the second beam-transmitting component 113 may be or include a waveguide, an integrated waveguide, an optical fiber, or another component capable of transmitting light beams. In some embodiments, the first beam-transmitting component 112 and the second beam-transmitting component 113 may be distinct portions of a same waveguide, optical fiber or other light transmitting component. The first beam-transmitting component 112 and the second beam-transmitting component 113 are configured to transmit the light resonating in the cavities. The first beam-transmitting component 112 is optically coupled to the wavelength selective elements 131-133 such that the light having the first wavelength from the gain medium 104 is transmitted to the first wavelength selective element 131, the light having the second wavelength from the gain medium 104 is transmitted to the second wavelength selective element 132, and the light having the third wavelength from the gain medium 104 is transmitted to the third wavelength selective element 133. The wavelength selective elements 131-133 are optically coupled to the second beam-transmitting component 113 at the other end (the top part of the wavelength selective elements 131-133 in FIG. 1) to which the light filtered by the wavelength selective elements 131-133 is transmitted. The second beam-transmitting component 113 transmits the filtered light to the chirped grating reflector 116.

In FIG. 1, the multi-wavelength external cavity laser device 100 is shown to include the chirped grating reflector 116. The chirped grating reflector 116 includes a mirror having chirped spaces that vary in depth in a manner designed to reflect light having different wavelengths (e.g., λ1-λ3) at different portions of the mirror. In some embodiments, the chirped grating reflector 116 may include a plurality of dielectric layers, wherein the chirped spaces are located between the dielectric layers. In those embodiments, the chirped grating reflector 116 is a linearly chirped mirror designed to reflect light having certain wavelengths (e.g., λ1-λ3), while not reflecting light having some wavelengths. As a result, light having wavelengths which the chirped grating reflector 116 is designed to reflect will be reflected back to the cavity and will be allowed to resonate in the cavity. In some embodiments, the light having the first wavelength and the light having the second wavelength are reflected from a different portion of the chirped grating reflector 116. In some embodiments, the first wavelength is different from the second wavelength.

The chirped grating reflector 116 can be designed in various ways. In some embodiments, the chirped grating reflector 116 may be designed in a configuration where light having the wavelengths λ1-λ3 may be reflected back at different locations within the chirped grating reflector 116. For example, light having the first wavelength λ1 may be reflected at a first portion of the chirped grating reflector 116, while light having the second wavelength λ2 may be reflected at a second portion of the chirped grating reflector 116. Thus, with the reflector 108 being one end of the optical cavity, the first portion of the chirped grating reflector 116 serves as the other end of the optical cavity (i.e., a first optical cavity) for the light having the first wavelength (λ1), and the second portion of the chirped grating reflector 116 serves as the other end of the optical cavity (i.e., a second optical cavity) for the light having the second wavelength (λ2). In some embodiments, the multi-wavelength external cavity laser device 100 may emit a laser output through the chirped grating reflector 116. For example, the multi-wavelength external laser device 100 may emit light having the first wavelength through the first portion of the chirped grating reflector 116, and emit light having the second wavelength through the second portion of the chirped grating reflector 116. In some embodiments, the ratio of a change in the length of the first optical cavity to the length of the first optical cavity is approximately equal to the ratio of a wavelength change of light resonating in the first optical cavity to a center wavelength of a total wavelength tuning range of the first optical cavity, while the ratio of a change in the length of the second optical cavity to the length of the second optical cavity is approximately equal to the ratio of a wavelength change of light resonating in the second optical cavity to a center wavelength of a total wavelength tuning range of the second optical cavity. This allows for synchronization of the light resonating in the respective cavity. One such embodiment is described in U.S. Pat. No. 9,490,607, which is incorporated herein by reference in its entirety.

In FIG. 1, the multi-wavelength external cavity laser device 100 is shown to include the wavelength selective elements 131-133. The first wavelength selective element 131 is configured to filter light having the first wavelength (λ1), the second wavelength selective element 132 is configured to filter light having the second wavelength (λ2), and the third wavelength selective element 133 is configured to filter light having the third wavelength (λ3). Thus, the wavelength selective elements 131-133 allow each light having each of the wavelengths λ1-λ3 to travel the corresponding path (i.e., the paths 151, 152, and 153, respectively). In some embodiments, the wavelength selective elements 131-133 may be or include a micro-ring resonator, a double-ring resonator (which is shown in FIG. 1), a resonator with any number of rings, a ladder filter, a diffraction grating filter, a distributed bragg grating filter, or a tunable wavelength filter. In some embodiments, the first wavelength selective element 131 and the second wavelength selective element 132 are connected in parallel as depicted in FIG. 1 such that a portion of the first beam-transmitting component 112 is connected between the gain medium 104 and each of the wavelength selective elements 131-133, and such that a portion of the second beam-transmitting component 113 is connected between the chirped grating reflector 116 and each of the wavelength selective elements 131-133. In some embodiments, the first wavelength is different from the second wavelength.

In some embodiments, the wavelength selective elements 131-133 may be or include a tunable wavelength filter. By adjusting the tunable wavelength filter (e.g., by adjusting an effective refractive index or an effective path length), light may be filtered at a different wavelength. In this case, the light may be reflected at a shifted portion of the chirped grating reflector 116, wherein the shifted portion is different from the portion the light would be reflected off of without the adjustment. In some embodiments, the first wavelength selective element 131 is a first tunable wavelength filter, and the second wavelength selective element 132 is a second tunable wavelength filter, wherein each of the tunable wavelength filters may operate independently. This allows for lasing at multiple tunable wavelengths without having to physically add or adjust any component.

The components described herein can be arranged and define an optical cavity in various manners. For example, in some embodiments, the chirped grating reflector 116 may be an output end of an optical cavity. In some embodiment, the chirped grating reflector 116 may be a fiber bragg grating included in the beam-transmitting component 112 (e.g., an optical fiber). In some embodiments, for example in FIG. 1, although the multi-wavelength external cavity laser device 100 is depicted to include three wavelength selective elements, the multi-wavelength external cavity laser device 100 may include any number of wavelength selective elements. For example, in some embodiments, the multi-wavelength external cavity laser device 200 may include a plurality of wavelength selective elements and may be configured to operate at a plurality of wavelengths. For example, the multi-wavelength external cavity laser device 100 may include more than three wavelength selective elements optically coupled to the gain medium and the reflector, and each of the plurality of wavelength selective elements may be configured to filter light having a respective wavelength. For example, the chirped grating reflector 116 may include a plurality of portions, each of which is configured to reflect light having a respective wavelength.

Multi-wavelength external cavity laser devices described herein (e.g., the multi-wavelength external cavity laser device 100) may be designed to operate in various manners. In some embodiments, for example, a reflector (e.g., the reflector 108) of a multi-wavelength external cavity laser device may be a cavity end, and the multi-wavelength external cavity laser device may be configured to emit a laser output through the reflector. In some embodiments, the output may be adjusted by for example, controlling the reflectivity of the reflector. In some embodiments, a chirped grating reflector (e.g., the chirped grating reflector 116) may be a cavity end, and the multi-wavelength external cavity laser device may be configured to emit a laser output through the chirped grating reflector. In some embodiments, the output may be adjusted by for example, controlling the chirped grating reflector and/or the reflectivity of the chirped grating reflector. In some embodiments, each of the reflector and the chirped grating reflector may form a cavity end, and the multi-wavelength external cavity laser device may be configured to emit a laser output through either of the reflector or the chirped grating reflector, or both. For example, the multi-wavelength external cavity laser device may selectively emit a laser output through one of the cavity ends by controlling the reflectivity of the reflector and/or the chirped grating reflector. For example, the reflector and/or the chirped grating reflector may be controlled to have different reflectivities such that the multi-wavelength external cavity laser device can emit different laser outputs at each of the cavity ends.

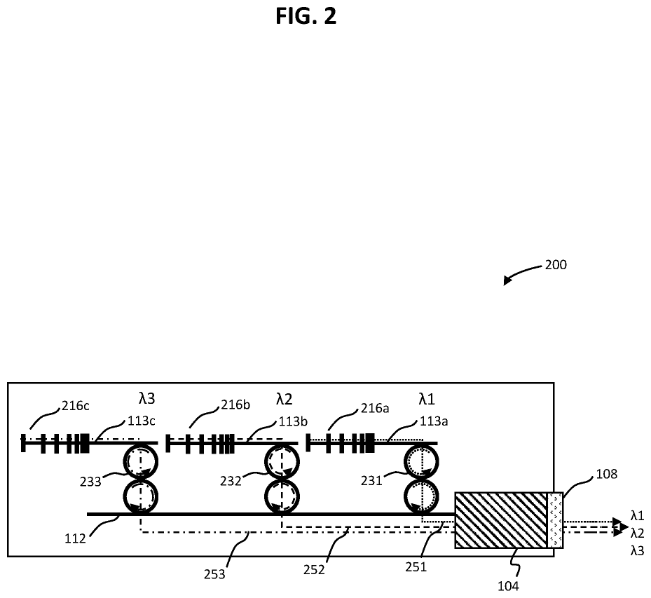

FIG. 2 depicts a multi-wavelength external cavity laser device 200 that includes a gain medium 104, a reflector 108, a first beam-transmitting component 112, a second beam-transmitting component 113a, a third beam-transmitting component 113b, a fourth beam-transmitting component 113c, a first chirped grating reflector 216a, a second chirped grating reflector 216b, a third chirped grating reflector 216c, a first wavelength selective element 231, a second wavelength selective element 232, and a third wavelength selective element 233. These components are similar or the same as the corresponding components described in FIG. 1, but the multi-wavelength external cavity laser device 200 further includes multiple chirped grating reflectors (e.g., 216a-c). The wavelength selective elements 231-233 are optically coupled to the gain medium 104 and the reflector 108 via the first beam-transmitting component 112. The first chirped grating reflector 216a is optically coupled to the first wavelength selective element 231, the second chirped grating reflector 216b is optically coupled to the second wavelength selective element 232, and the third chirped grating reflector 216c is optically coupled to the third wavelength selective element 233. A first light path 251 for a first wavelength (λ1), a second light path 252 for a second wavelength (λ2), and a third light path 253 for a third wavelength (λ3) are depicted as different dashed lines. In some embodiments, the first wavelength is different from the second wavelength.

In FIG. 2, the multi-wavelength external cavity laser device 200 is shown to include the beam-transmitting components 112 and 113a-c. The beam-transmitting components 112 and 113a-c may be or include a waveguide, an integrated waveguide, or an optical fiber or respective portions thereof. The beam-transmitting components 112 and 113a-c are configured to transmit the light resonating in the cavities. The beam-transmitting component 112 is optically coupled to the wavelength selective elements 231-233 such that the light having the first wavelength (λ1) from the gain medium 104 is transmitted to the first wavelength selective element 231, the light having the second wavelength (λ2) from the gain medium 104 is transmitted to the second wavelength selective element 232, and the light having the third wavelength (λ3) from the gain medium 104 is transmitted to the third wavelength selective element 233. Each of the wavelength selective elements 231-233 is optically coupled to each of the beam-transmitting components 113a-c respectively at the other end (the top part of the wavelength selective elements 231-233 in FIG. 2). The light having the first wavelength (λ1) (i.e., filtered by the first wavelength selective element 231) is directed to the first chirped grating reflector 216a via the second beam-transmitting component 113a, the light having the second wavelength (λ2) (i.e., filtered by the second wavelength selective element 232) is directed to the second chirped grating reflector 216b via the third beam-transmitting component 113b, and the light having the third wavelength (λ3) (i.e., filtered by the third wavelength selective element 233) is directed to the third chirped grating reflector 216c via the fourth beam-transmitting component 113c.

In FIG. 2, the light having the first wavelength (λ1) is reflected off of the first chirped grating reflector 216a, as shown along the first light path 251, the light having the second wavelength (λ2) is reflected off of the second chirped grating reflector 216b, as shown along the second light path 252, and the light having the third wavelength (λ3) is reflected off of the third chirped grating reflector 216c, as shown along the third light path 253. The light having the first wavelength (λ1) travels the first light path 251 (i.e., through the first wavelength selective element 231), the light having the second wavelength (λ2) travels the second light path 252 (i.e., through the second wavelength selective element 232), and the light having the third wavelength (λ3) travels the third light path 253 (i.e., through the third wavelength selective element 233). After reflecting off of the respective chirped grating reflectors (i.e., 216a-c), the light travels back through the respective wavelength selective elements 231-233 and back through the gain medium 104. In some embodiments, a portion of the light may be emitted through the reflector 108.

In some embodiments, with the reflector 108 being one end of the optical cavity, the first chirped grating reflector 216a serves as the other end of the optical cavity (i.e., first optical cavity) for the light having the first wavelength (λ1), the second chirped grating reflector 216b serves as the other end of the optical cavity (i.e., second optical cavity) for the light having the second wavelength (λ2), and the third chirped grating reflector 216c serves as the other end of the optical cavity (i.e., third optical cavity) for the light having the third wavelength (λ1). In some embodiments, the ratio of a change in the length of the first optical cavity to the length of the first optical cavity is approximately equal to the ratio of a wavelength change of light resonating in the first optical cavity to a center wavelength of a total wavelength tuning range of the first optical cavity, the ratio of a change in the length of the second optical cavity to the length of the second optical cavity is approximately equal to the ratio of a wavelength change of light resonating in the second optical cavity to a center wavelength of a total wavelength tuning range of the second optical cavity, and the ratio of a change in the length of the third optical cavity to the length of the third optical cavity is approximately equal to the ratio of a wavelength change of light resonating in the third optical cavity to a center wavelength of a total wavelength tuning range of the third optical cavity. This allows for synchronization of the light resonating in the respective cavity. One such embodiment is described in U.S. Pat. No. 9,490,607, which is incorporated herein by reference in its entirety.

In FIG. 2, the multi-wavelength external cavity laser device 200 is shown to include the wavelength selective elements 231-233, which are essentially the same as described in FIG. 1, but each of the wavelength selective elements 231-233 is coupled to its own chirped grating reflector (i.e., 216a-c). Thus, the wavelength selective elements 231-233 filter the light resonating within the respective optical cavity. In some embodiments, the first wavelength is different from the second wavelength. Although the multi-wavelength external cavity laser device 200 is depicted to include three wavelength selective elements (i.e., 231-233) and three chirped grating reflectors (i.e., 216a-c), the multi-wavelength external cavity laser device 200 may include any number of wavelength selective elements and chirped grating reflectors. For example, in some embodiments, the multi-wavelength external cavity laser device 200 may include one wavelength selective element and one chirped grating reflector, wherein different resonant modes filtered by the wavelength selective element may be reflected from respective portions of the chirped grating reflector thereby forming different optical cavities and generating laser outputs at different wavelengths. For example, in some embodiments, the multi-wavelength external cavity laser device 200 may include a plurality of wavelength selective elements and a plurality of chirped grating reflectors, each of which is optically coupled to the respective wavelength selective element. In this manner, the multi-wavelength external cavity laser device can form a plurality of optical cavities therein and can generate laser outputs at a plurality of wavelengths.

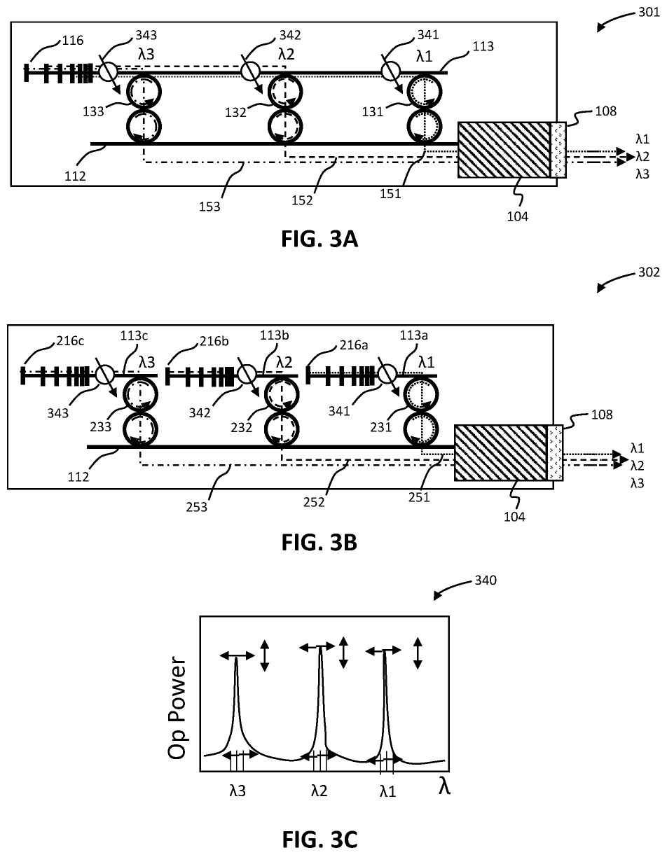

FIGS. 3A-3C relate generally to multi-wavelength external cavity laser devices that further include a beam-controlling component and a characteristic profile of light emitted from said devices. FIGS. 3A and 3B depict multi-wavelength external cavity laser devices 301 and 302 that further include beam-controlling components. In some embodiments, the multi-wavelength external cavity laser devices 301 and 302 may include optical attenuators 341-343 to control the power of light, as shown in FIG. 3A and FIG. 3B. FIG. 3C depicts an exemplary power profile 340 of output light whose power can be controlled by the optical attenuators 341-343. The multi-wavelength external cavity laser device 301 is the multi-wavelength external cavity laser device 100 equipped with the optical attenuators 341-343, and the multi-wavelength external cavity laser device 302 is the multi-wavelength external cavity laser device 200 equipped with the optical attenuators 341-343. The optical attenuators 341-343 may be or include a fiber optic attenuator or any device to control a characteristic of light such as the power level of light. The optical attenuators 341-343 may be or include any optical component configured to absorb, reflect, diffuse, scatter, deflect, diffract, or disperse light. Although the optical attenuators 341-343 are shown to be located between the chirped grating reflector (e.g., 116) and the wavelength selective element (e.g., 131), the optical attenuators 341-343 may be located anywhere between the chirped grating reflector and the wavelength selective element.

The optical attenuators 341-343 are configured to control a characteristic of light passing through the optical attenuators 341-343. In some embodiments, the power level of light may be controlled by the optical attenuators 341-343 as shown in the profile 340. For example, in the multi-wavelength external cavity laser device 301, as shown in FIG. 3A, the optical attenuator 341 is coupled to the first wavelength selective element 131 and is configured to control a power level of the light having the first wavelength (λ1) as shown in the profile 340 of FIG. 3C. This allows for controlling the light having the first wavelength (λ1), separately from the light having the second or third wavelength. In some embodiments, the full width at half maximum (FWHM) of the light profile may be controlled. Optical attenuators are described as a non-limiting example, and any component that can control a characteristic of light may be included as a beam-controlling component. In some embodiments, for example, a polarizer or a polarizing filter may be a beam-controlling component, and the polarization state of light may be controlled. In some embodiments, for example, the beam-controlling component may be or include an absorber so as to absorb a portion of light (e.g., to absorb a portion of light having a first wavelength, and/or to absorb light having a first wavelength while transmitting light having a second wavelength). In some embodiments, for example, the beam-controlling component may be or include a modulator configured to modulate light (e.g., phase, etc.).

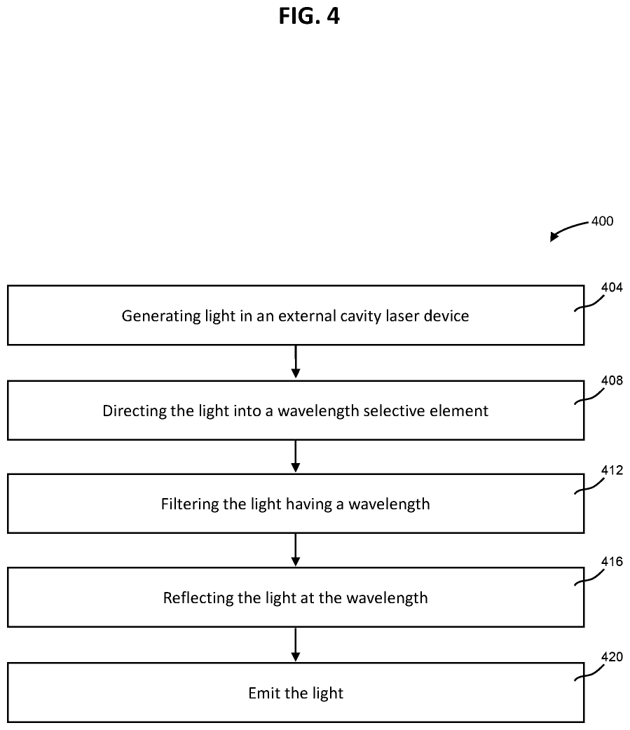

FIG. 4 depicts a flow diagram of a method 400 of utilizing a multi-wavelength external cavity laser device. Any type of multi-wavelength external cavity laser devices, including, but not limited to, devices described with respect to FIG. 1, FIG. 2, and FIG. 3 may be used to perform the method described herein. At an operation 404, the method 400 includes generating light having a first wavelength in a multi-wavelength external cavity laser device. A gain medium can be provided with an external source of energy (e.g., an outside light source, an electric field, etc.), which causes the gain medium to generate stimulated photons (i.e., light). In some embodiments, the light may have the first wavelength and a second wavelength.

At an operation 408, the method 400 includes directing the light generated at the operation 404 to a wavelength selective element via a beam-transmitting component. In some embodiments, the light directed to the wavelength selective element may be at the first wavelength, a second wavelength, or a range of wavelengths. At the operation 408, the method 400 may include directing the light generated at the operation 404 into the wavelength selective element after reflecting off of a reflector. The reflector serves as a mirror that forms one end of an optical cavity. In some embodiments, the method 400 may include reflecting essentially all the light generated off of the reflector. In some embodiments, the method 400 may include reflecting at least a portion of light having the first wavelength off of the reflector. The reflector may be or include any material, component, or device that can reflect light having at least the first wavelength. In some embodiments, the reflector may be a loop mirror. In some embodiments, the reflector may be omitted-in this case, partial/high reflective coating on the gain medium and/or a portion of the multi-wavelength external cavity laser device may reflect the light.

At an operation 412, the method 400 includes filtering the light having the first wavelength by the first wavelength selective element, and filtering the light having the second wavelength by the second wavelength selective element. In some embodiments, the wavelength selective element filters the light having one or more wavelengths or a range of wavelengths. In some embodiments, the filtering wavelength(s) may be tunable. In some embodiments, this filtering may include resonating (e.g., by a micro-ring resonator filter), absorbing, band-passing, polarizing, or interfering light at one or more particular wavelengths. For example, the filtering may include resonating light at a wavelength or wavelengths by constructive interference. For example, the filtering may include transmitting light having a wavelength or wavelengths to be filtered while absorbing (or blocking, scattering, etc.) light having the other wavelengths.

At an operation 416, the method 400 includes reflecting the light having the first wavelength by a first portion of a first chirped grating reflector. The light having the first wavelength travels back to the reflector through the first wavelength selective element. As a result, the first portion of the first chirped grating reflector and the reflector define a first optical cavity. In some embodiments, the method 400 may include reflecting the light having the second wavelength by a second portion of the first chirped grating reflector. The light having the second wavelength travels back to the reflector through the second wavelength selective element. As a result, the second portion of the first chirped grating reflector and the reflector define a second optical cavity. In some embodiments, the method 400 may include reflecting the light having the second wavelength by a second chirped grating reflector. The light having the second wavelength travels back to the reflector through the second wavelength selective element. As a result, the second chirped grating reflector and the reflector define a second optical cavity.

In some embodiments, the method 400 may include reflecting, by a second portion of the first chirped grating reflector, a portion of light having the second wavelength. The light having the second wavelength travels back to the reflector through the second wavelength selective element. As a result, the second portion of the chirped grating reflector and the reflector define a second optical cavity. In some embodiments, the ratio of a length change of the first optical cavity to the length of the first optical cavity is approximately equal to the ratio of a wavelength change of light resonating in the first optical cavity to a center wavelength of a total wavelength tuning range of the first optical cavity, while the ratio of a length change of the second optical cavity to the length of the second optical cavity is approximately equal to the ratio of a wavelength change of light resonating in the second optical cavity to a center wavelength of a total wavelength tuning range of the second optical cavity. This allows for synchronization of the light resonating in the respective cavity. One such embodiment is described in U.S. Pat. No. 9,490,607, which is incorporated herein by reference in its entirety.

In some embodiments, the method 400 may include reflecting, by a second chirped grating reflector, a portion of light having a second wavelength. The light having the second wavelength travels back to the reflector through the second wavelength selective element. As a result, the first chirped grating reflector and the reflector define a first optical cavity, and the second chirped grating reflector and the reflector define a second optical cavity. In some embodiments, the ratio of a length change of the first optical cavity to the length of the first optical cavity is approximately equal to the ratio of a wavelength change of light resonating in the first optical cavity to a center wavelength of a total wavelength tuning range of the first optical cavity, while the ratio of a length change of the second optical cavity to the length of the second optical cavity is approximately equal to the ratio of a wavelength change of light resonating in the second optical cavity to a center wavelength of a total wavelength tuning range of the second optical cavity. This allows for synchronization of the light resonating in the respective cavity. One such embodiment is described in U.S. Pat. No. 9,490,607, which is incorporated herein by reference in its entirety.

At an operation 420, the method 400 includes emitting the light at the first wavelength. In some embodiments, the method 400 includes emitting the light at the first wavelength, the second wavelength, a range of wavelengths, and/or a tunable wavelength. In some embodiments, the method 400 may include emitting the light through the reflector. In some embodiments, the method 400 may include emitting the light through the chirped grating reflector, wherein the chirped grating reflector is placed at an output side of the optical cavity.

In some embodiments, the method 400 may include controlling a characteristic of the light. For example, the method 400 may include controlling a power level of light using an optical attenuator. This allows for controlling individual light having a wavelength, separately from light having other wavelengths. In some embodiments, the method 400 may include controlling the full width at half maximum (FWHM) of the light profile. Controlling a power level or the FWHM of light is a non-limiting example, and the method 400 may include, in some embodiments, controlling other characteristics of light including polarization states.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can of course vary. It is also to be understood that the terminology used herein is for the purpose of describing particular embodiments only, and is not intended to be limiting.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Additional embodiments may be set forth in the following claims.

What is claimed is:

1. A multiple wavelength external cavity laser device, comprising:
a gain medium;
a reflector optically coupled to the gain medium;
a first wavelength selective element optically coupled to the gain medium and the reflector, the first wavelength selective element configured to filter light having a first wavelength; and
a first chirped grating reflector optically coupled to the first wavelength selective element, wherein the first chirped grating reflector is configured to reflect a plurality of wavelengths including the first wavelength.

2. The device of claim 1, further comprising:
a second wavelength selective element configured to filter light having a second wavelength, the second wavelength selective element optically coupled to the gain medium and the reflector;
wherein the first chirped grating reflector is optically coupled to the second wavelength selective element, and wherein:
a first portion of the first chirped grating reflector is configured to reflect the light having the first wavelength; and
a second portion of the first chirped grating reflector is configured to reflect the light having the second wavelength.

3. The device of claim 2, wherein the light having the first wavelength and the light having the second wavelength are reflected from a different portion of the chirped grating reflector.

4. The device of claim 2, wherein:
the first wavelength selective element and the second wavelength selected element are connected in parallel; and
the first wavelength is different from the second wavelength.

5. The device of claim 2, wherein:
the reflector and the first portion of the chirped grating reflector define a first optical cavity, such that the first wavelength selective element is located along a path of light resonating in the first optical cavity; and
the reflector and the second portion of the first chirped grating reflector define a second optical cavity, such that the second wavelength selective element is located along a path of light resonating in the second optical cavity.

6. The device of claim 5, wherein:
the ratio of a length change of the first optical cavity to the length of the first optical cavity is approximately equal to the ratio of a wavelength change of light resonating in the first optical cavity to a center wavelength of a total wavelength tuning range of the first optical cavity; and
the ratio of a length change of the second optical cavity to the length of the second optical cavity is approximately equal to the ratio of a wavelength change of light resonating in the second optical cavity to a center wavelength of a total wavelength tuning range of the second optical cavity.

7. The device of claim 1, further comprising:
a second wavelength selective element configured to filter light having a second wavelength, the second wavelength selective element optically coupled to the gain medium and the reflector; and
a second chirped grating reflector configured to reflect the light having the second wavelength, the second chirped grating reflector optically coupled to the second wavelength selective element.

8. The device of claim 7, wherein:
the first wavelength is different from the second wavelength.

9. The device of claim 7, wherein:
the reflector and the first chirped grating reflector define a first optical cavity, such that the first wavelength selective element is located along a path of light resonating in the first optical cavity; and
the reflector and the second chirped grating reflector define a second optical cavity, such that the second wavelength selective element is located along a path of light resonating in the second optical cavity.

10. The device of claim 9, wherein:
the ratio of a length change of the first optical cavity to the length of the first optical cavity is approximately equal to the ratio of a wavelength change of light resonating in the first optical cavity to a center wavelength of a total wavelength tuning range of the first optical cavity; and
the ratio of a length change of the second optical cavity to the length of the second optical cavity is approximately equal to the ratio of a wavelength change of light resonating in the second optical cavity to a center wavelength of a total wavelength tuning range of the second optical cavity.

11. The device of claim 1, wherein:
the first wavelength selective element comprises a wavelength tunable filter.

12. The device of claim 1, wherein:
the first wavelength selective element comprises a micro-ring resonator filter.

13. The device of claim 1, further comprising:
a beam-controlling component optically coupled to the first wavelength selective element, the beam-controlling component configured to control a characteristic of the light.

14. A method of utilizing a multi-wavelength external cavity laser device, the method comprising:
generating light in an external cavity laser device, wherein the light has a plurality of wavelengths;
directing or reflecting by a reflector, the light into a first wavelength selective element;
filtering, by the first wavelength selective element, a portion of the light at a first wavelength;
reflecting, by a first portion of a chirped grating reflector, the portion of the light at the first wavelength;
emitting the light at the first wavelength.

15. The method of claim 14, further comprising:
filtering, by a second wavelength selective element, a portion of the light at a second wavelength; and
reflecting, by a second portion of the chirped grating reflector, the portion of the light at the second wavelength.

16. The method of claim 15, wherein:
the reflector and the first portion of the chirped grating reflector define a first optical cavity, such that the first wavelength selective element is located along a path of light resonating in the first optical cavity;
the ratio of a length change of the first optical cavity to the length of the first optical cavity is approximately equal to the ratio of a wavelength change of light resonating in the first optical cavity to a center wavelength of a total wavelength tuning range of the first optical cavity;
the reflector and the second portion of the chirped grating reflector define a second optical cavity, such that the second wavelength selective element is located along a path of light resonating in the second optical cavity; and
the ratio of a length change of the second optical cavity to the length of the second optical cavity is approximately equal to the ratio of a wavelength change of light resonating in the second optical cavity to a center wavelength of a total wavelength tuning range of the second optical cavity.

17. The method of claim 14, further comprising:
filtering, by a second wavelength selective element, a portion of the light at a second wavelength; and
reflecting, by a second chirped grating reflector, the portion of the light at the second wavelength.

18. The method of claim 17, wherein:
the reflector and the first chirped grating reflector define a first optical cavity, such that the first wavelength selective element is located along a path of light resonating in the first optical cavity;
the ratio of a length change of the first optical cavity to the length of the first optical cavity is approximately equal to the ratio of a wavelength change of light resonating in the first optical cavity to a center wavelength of a total wavelength tuning range of the first optical cavity;
the reflector and the second chirped grating reflector define a second optical cavity, such that the second wavelength selective element is located along a path of light resonating in the second optical cavity; and
the ratio of a length change of the second optical cavity to the length of the second optical cavity is approximately equal to the ratio of a wavelength change of light resonating in the second optical cavity to a center wavelength of a total wavelength tuning range of the second optical cavity.

19. The method of claim 14, wherein the first wavelength selective element comprises a micro-ring resonator filter.

20. The method of claim 14, further comprising controlling, by a beam-controlling component, a characteristic of the light.
